(19) United States
(12) Patent Application Publication
(10) Pub. No.: US 2006/0065197 A1
(43) Pub. Date: Mar. 30, 2006

(54) Vapor deposition apparatus

(76) Inventors: Eiji Yamada, Mihara-shi (JP); Takayuki Yuasa, Ikoma-gun (JP); Masahiro Araki, Ube-shi (JP); Nakao Akutsu, Tokyo (JP)

Correspondence Address: HARNESS, DICKEY & PIERCE, P.L.C., P.O. BOX 8910, RESTON, VA, 20195, US

(21) Appl. No.: 11/235,188

(22) Filed: Sep. 27, 2005

(30) Foreign Application Priority Data
Sep. 27, 2004 (JP) 2004-279420

(51) Int. Cl. C23C 16/00

(52) U.S. Cl. 118/728

(57) ABSTRACT

A vapor deposition apparatus of the present invention has a substrate holder having a substrate holding surface for holding a substrate thereon, and a flow channel for supplying a source gas onto the substrate. The flow channel has an upper wall and a lower wall. An aperture portion is provided in the lower wall of the flow channel. The substrate holding surface of the substrate holder fits in the aperture portion while forming a space between the substrate holding surface and the aperture portion. A means for reducing leakage of gas through the space between the aperture portion and the substrate holder is provided. With this structure, since a means for reducing leakage of gas through the space between the aperture portion and the substrate holder is provided, the conductance with respect to outflow of gas increases, which in turn reduces variations in the amount of outflow gas. This results in high yield production of nitride semiconductor devices with a long life and high light-emission efficiency.

This non-provisional application claims priority under 35 U.S.C. §119(a) on Japanese Patent Application No. 2004-279420 filed in Japan on Sep. 27, 2004, the entire contents of which are hereby incorporated by reference.

### BACKGROUND OF THE INVENTION

The present invention generally relates to vapor deposition apparatuses, and more particularly to vapor deposition apparatuses improved for high yield production of nitride semiconductor devices.

Nitride-based group III-V compound semiconductor crystals represented by GaN, InGaN, AlGaN, AlInGaN, etc., have direct-transition-type band gaps and are expected to be applied to semiconductor laser devices. InGaN mixed crystals enable red-to-ultraviolet light emission and thus are attracting special attention as short-wavelength material. These crystals are already in practical use as light emitting diode devices with wavelengths ranging from ultraviolet to green and as bluish purple laser diode devices. Generally, these devices are produced by the metal organic chemical vapor deposition (MOCVD) method by using CVD apparatuses. Specifically, GaN-type, InGaN-type, AlGaN-type, InGaNP-type, InGaNAs-type, and InGaAlN-type nitride semiconductor films are grown over a substrate. CVD apparatuses that grow these semiconductor films with the use of organic metal material are referred to as MOCVD apparatuses.

FIG. 9 shows a schematic cross-section of a conventional MOCVD apparatus (see, for example, Japanese Patent Publication No. 2001-19590). The conventional MOCVD apparatus has reaction chamber 31. Reaction chamber 31 houses flow channel 32 that effectively supplies source gas onto substrate 33, substrate holder 34 that holds substrate 33 on substrate holding surface 34a, and heater 35 that heats substrate holder 34. Flow channel 32 has upper wall 32a and lower wall 32b that has aperture portion 36. Substrate holding surface 34a of substrate holder 34 fits in aperture portion 36 while forming a space between substrate holding surface 34a and aperture portion 36. Substrate 33 and substrate holding surface 34a of substrate holder 34 come in contact with the gas flowing in flow channel 32. As shown by the arrows, source gas is supplied from gas supply port 37 and flows through flow channel 32 onto substrate 33, where the gas contributes to growth of nitride semiconductor films. Substrate 33 and substrate holder 34 are revolved by revolution of revolving axis 39. Source gas that does not contribute to growth of semiconductor films is released from gas exhausting port 38. Also provided in reaction chamber 31 is automatic carry-in/out equipment, not shown, that carries in and out substrate 33 and substrate holder 34 (see, for example, Japanese Patent Application Publication No. 2003-17544).

Production of nitride-based semiconductor lasers made of GaN, AlN, InN, and mixed crystals thereof with the use of conventional MOCVD apparatuses is problematic in that the crystallinity and thickness of the grown film are not uniform throughout the substrate. Also, there are variations between substrates. As a result, the nitride-based semiconductor layers prepared over a substrate are found to suffer crystal distortions and multiple cracks.

Crystal defects including cracks act as the center of non-emitting combination; the defects act as paths for current to cause leakage current, posing the problem of poor yields. Particularly with LD devices, the defects cause an increase in threshold current density, posing the problem of shortened device life. Thus, it is important to reduce crystal defects including cracks.

The present inventors studied the cause of crystal defects including cracks. As a result, it has been found that the concentration distribution and amount of supply of source gas supplied on the substrate vary, which is because the amount of outflow of gas through the space between aperture portion 36 of flow channel 32 and substrate holder 34 is not constant. In MOCVD growth of nitride-based semiconductors, it was found that this effect was important and the uniformity of crystallinity in a crystal film and the uniformity of the thickness in a crystal film plane were not secured.

The present inventors have found the causes of variations in concentration distribution and amount of supply of source gas, which will be described below.

FIG. 10 is a view describing the cause of variations in the amount of outflow of gas through the space between the aperture portion of the flow channel and the substrate holder. In MOCVD apparatuses, there is space 21 between aperture portion 36 of flow channel 32 and substrate holder 34. Provision of space 21 is because substrate holder 34 needs to be revolved in the direction R for the purpose of uniform crystal growth throughout the substrate plane. Space 21 is provided also because substrate holder 34 needs to be movable for substrate 33 on substrate holder 34 to be carried in from the outside of reaction chamber 31.

Substrate 33 is carried in as follows. First, heater 35 is kept apart from flow channel 32. Substrate holder 34 with substrate 33 thereon is then mounted on heater 35 (referred to as catching). For positioning, engagement is provided in the part that heater 35 and substrate holder 34 touch. Heater 35 and substrate holder 34 are then moved to flow channel 32, and set such that substrate 33 is placed appropriately relative to flow channel 32.

Because substrate holder 34 expands when heated, or in view of the catching accuracy of substrate holder 34 and heater 35, the engagement need some tolerance. Also some tolerance is necessary to space 21, which is between aperture portion 36 of flow channel 32 and substrate holder 34. At the time of automatic carry-in/out, if revolving axis 39 is off the center of substrate holder 34, this location is referred to as a catching error. In this case, substrate holder 34 is revolved with a varying space relative to aperture portion 36 of flow channel 32. Because of the accuracy of axis processing, revolving axis 39 is generally eccentric to some extent. The axis eccentricity causes variations in space 21, which is between aperture portion 36 of flow channel 32 and substrate holder 34 (the axis eccentricity causing wobbling 22). Under these circumstances the amount of outflow gas 23 varies, which in turn causes biased-flow of source gas, i.e., bias of gas concentration distribution on substrate 33. Also, the gas concentration distribution on substrate 33 is not steady.

The problem of variations in space 21, which is between aperture portion 36 of flow channel 32 and substrate holder 34, also occurs at the time of automatically remounting flow channel 32 and substrate holder 34 after removal thereof for washing. Further, because of the processing accuracy of flow channel 32 and substrate holder 34, it is difficult to repeat the initial positioning, which means space 21 of different size after renewal of flow channel 32 and substrate holder 34.

Since the extent of the above problem varies between apparatuses, growth conditions need to be optimized for each individual apparatus. In nitride-based semiconductor, re-evaporation of the crystal happens because of its high saturated vapor pressure. In accordance with variations in the concentration distribution and amount of supply of source gas, the ratio of III source gas and V source gas also varies. Consequently, crystallinity does not become uniform in a crystal film plane and the thickness does not become uniform in a crystal film plane. Thus, variations in the amount of outflow gas seriously affect crystal growth.

### SUMMARY OF THE INVENTION

In view of the foregoing and other problems, it is an object of the present invention to provide a vapor deposition apparatus improved for stable gas distribution throughout the substrate.

It is another object of the present invention to provide a vapor deposition apparatus improved for a stable amount of outflow gas.

It is another object of the present invention to provide a vapor deposition apparatus improved to prevent crystallinity in a crystal film plane and the thickness in a crystal film plane from varying.

It is another object of the present invention to provide a vapor deposition apparatus that eliminates the need for optimization of growth conditions for each individual apparatus.

It is another object of the present invention to provide a vapor deposition apparatus that realizes high-yield production of light emitting devices of nitride semiconductor with a long life and high light-emission efficiency.

It is another object of the present invention to provide an MOCVD apparatus that realizes high light-emission efficiency and high-yield production of long-lived light emitting devices of nitride semiconductor.

In order to accomplish the above and other objects, the vapor deposition apparatus according to the present invention is a vapor deposition apparatus comprising: a substrate holder comprising a substrate holding surface for holding a substrate thereon; a flow channel for supplying a source gas onto the substrate, the flow channel comprising an upper wall and a lower wall; and an aperture portion provided in the lower wall of the flow channel. The substrate holding surface of the substrate holder fits in the aperture portion while forming a space between the substrate holding surface and the aperture portion. The apparatus also comprises a means for reducing leakage of gas through the space between the aperture portion and the substrate holder.

According to the invention, since a means for reducing leakage of gas through the space is provided between the aperture portion and the substrate holder, variations in the amount of outflow gas can be decreased.

The means for reducing leakage of gas is preferably formed by bending the space from the inside of the flow channel to the outside thereof.

The means for reducing leakage of gas preferably comprises: an upward dent portion dented in an upward direction, the upward dent portion being provided along a periphery of the aperture portion and in a thickness portion of the lower wall of the flow channel; and a brim projecting from a side wall of the substrate holder in a lateral direction, the brim fitting in the upward dent portion while forming a space between the brim and the upward dent portion, when the substrate holding surface of the substrate holder is in a state of fitting in the aperture portion.

With this structure, the space formed between the aperture portion of the flow channel and the substrate holder has a bent passage. The bent passage is composed of a first passage extending downward from the inside of the flow channel, a second passage extending in a lateral direction from the end of the first passage, and a third passage extending from the end of the second passage down to the outside of the flow channel.

Since the space is formed of a bent passage, the conductance with respect to outflow gas decreases, thus significantly reducing the amount of outflow gas through the space.

Another embodiment of the means for reducing leakage of gas comprises a brim projecting from a side wall of the substrate holder in a lateral direction, while forming a space between the brim and the lower wall of the flow channel, when the substrate holding surface of the substrate holder is in a state of fitting in the aperture portion.

With this structure, the space formed between the aperture portion of the flow channel and the substrate holder has a bent passage composed of a first passage extending downward from the inside of the flow channel and a second passage extending in a lateral direction from the end of the first passage to the outside of the flow channel.

When the space has a passage bent in this manner, the conductance with respect to outflow gas also decreases, thus reducing the amount of outflow gas through the space.

The vapor deposition apparatus may have a mechanism for revolving the substrate holder. With this structure, even if the substrate holder is rotated, variations in the amount of outflow gas can be decreased.

The vapor deposition apparatus preferably comprises: a heater for heating the substrate, the substrate holder holding the substrate being mounted on the heater, the heater being vertically movable and provided below the aperture portion of the flow channel; a mounting mechanism for mounting the substrate holder on the heater; and a moving mechanism for moving the heater with the substrate holder mounted thereon while fitting the substrate holding surface of the substrate holder in the aperture portion of the flow channel. According to this structure, variations in the amount of outflow gas are reduced at the time of automatically carrying in/out the substrate.

The substrate holder preferably comprises a disk comprising a brim provided along its side wall.

The vapor deposition apparatus is preferably used as an MOCVD apparatus for vapor deposition of a nitride semiconductor.

In the vapor deposition apparatus of the present invention, a means for reducing leakage of source gas through the space between the aperture portion of the flow channel and the substrate holder is provided. Source gas flowing from upstream in the flow channel is therefore not leaked through the space between the aperture portion of the flow channel and the substrate holder, or the amount of the gas leakage is significantly reduced. This reduces variations in outflow gas and thus assures uniformity of crystallinity and layer thickness of thin films throughout the substrate plane.

### BRIEF DESCRIPTION OF THE DRAWINGS

FIG. 1 is a schematic cross-section of a vapor deposition apparatus according to embodiment 1 of the present invention.

FIG. 2(a) is a cross-section of a vapor deposition apparatus that has a mechanism for revolving the substrate holder and a mechanism for automatically carrying in/out the substrate holder according to embodiment 1 of the present invention.

FIG. 2(b) is a plan view of a mechanism for carrying in/out the substrate holder.

FIG. 3 is an enlarged schematic cross-section of the part of fitting of the flow channel and substrate holder shown in FIG. 1.

FIG. 4 is a view showing a three-dimensional shape of the flow channel shown in FIG. 1 according to embodiment 1 of the present invention.

FIG. 5 is a graph of a comparison between the thickness distributions of GaN layers grown by using a conventional MOCVD apparatus and an MOCVD apparatus according to embodiment 1 of the present invention.

FIG. 6 is an enlarged schematic cross-section of the part of fitting of the flow channel and substrate holder according to embodiment 2 of the present invention.

FIG. 7 is a view showing a comparison between the thickness distributions of GaN layers grown by using a conventional MOCVD apparatus and an MOCVD apparatus according to embodiment 2 of the present invention.

FIG. 8 is a view schematically showing another specific example of the orifice structure.

FIG. 9 is a schematic cross-section of a conventional MOCVD apparatus.

FIG. 10(a) is a view describing the cause of variations in the amount of outflow gas through the space between the aperture portion of the flow channel and the substrate holder.

FIG. 10(b) is a plan view of the part of fitting of the flow channel and substrate holder.

### DESCRIPTION OF THE PREFERRED EMBODIMENTS

Preferred embodiments of the present invention will be described referring to drawings. It will be appreciated that the present invention is not limited to these embodiments.

A feature of the present invention is provision of a means for reducing leakage of gas through the space between the aperture portion and the substrate holder in order to reduce variations in the amount of outflow gas. This will be described in detail in embodiments 1 and 2 below.

### Embodiment 1

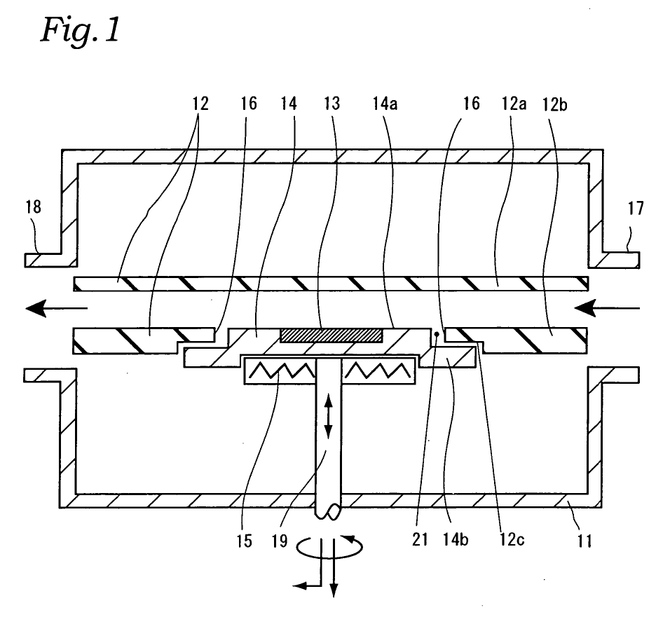

FIG. 1 is a cross-section of a vapor deposition apparatus according to embodiment 1. As in a conventional apparatus, this vapor deposition apparatus has, in reaction chamber 11, flow channel 12 that effectively supplies source gas onto substrate 13, substrate holder 14 that holds substrate 13, and heater 15 that heats substrate holder 14. Flow channel 12 has upper wall 12a and lower wall 12b. Through flow channel 12, source gas flows in parallel with substrate 13 from gas supply port 17 towards gas exhausting port 18. Lower wall 12b of flow channel 12 has aperture portion 16. Substrate holding surface 14a of substrate holder 14 fits in aperture portion 16 while forming space 21 between aperture portion 16 and substrate holder 14. Substrate 13 and substrate holding surface 14a of substrate holder 14 come in contact with the gas flowing in flow channel 12. Source gas is supplied from gas supply port 17 and flows through flow channel 12 onto substrate 13, where the gas contributes to growth of nitride semiconductor films. Source gas that does not contribute to growth of semiconductor films is released from gas exhausting port 18.

This vapor deposition apparatus is designed to reduce leakage of gas through space 21, which is between aperture portion 16 of flow channel 12 and substrate holder 14. A means for the reduction of gas leakage is composed of a combination of upward dent portion 12c and brim 14b. Upward dent portion 12c is dented in an upward direction, and is provided along the periphery of aperture portion 16 and in a thickness portion of lower wall 12b of flow channel 12. Brim 14b projects from the side wall of substrate holder 14 in a lateral direction. This will be described in greater detail later.

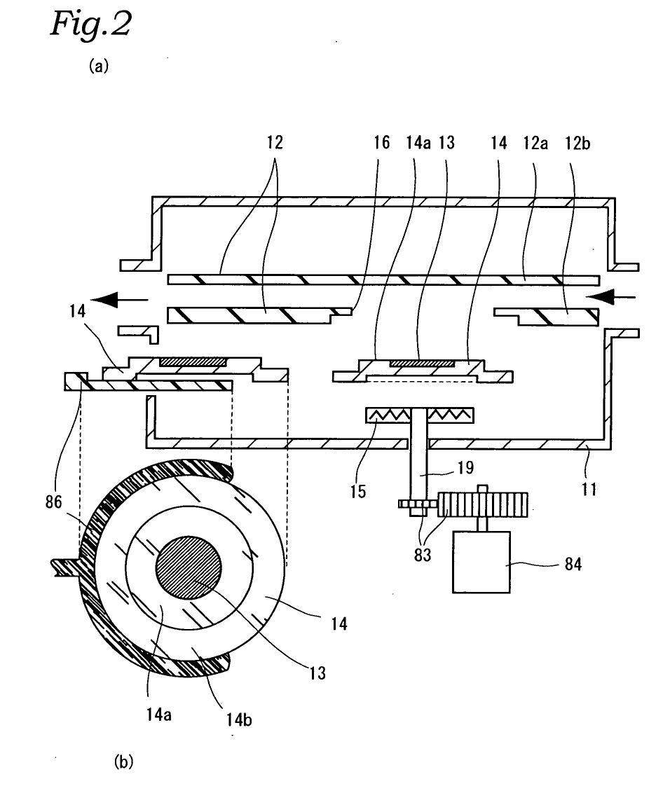

As shown in FIG. 2, the vapor deposition apparatus of the present invention may have a revolving mechanism for revolving substrate holder 14 and a mechanism for automatically carrying in/out substrate holder 14. As shown in the figure, substrate holder 14 is revolved by a revolving mechanism connected to revolving axis 19 that is mounted to heater 15. In the embodiment shown, substrate holder 14 is revolved by gear 83 mounted to revolving axis 19. Gear 83 is in turn revolved by a revolving means such as motor 84. Revolution may be transmitted by a belt or the like instead of by gear 83. Revolving axis 19, mounted to heater 15, protrudes from reaction chamber 11 to the outside thereof, where the axis is connected to gear 83.

The substrate is carried in as follows. As shown in FIG. 2, revolving axis 19 is vertically movable by a driving device, not shown. Before substrate 13 is carried in, heater 15 is kept apart from flow channel 12 (for example, below flow channel 12). Under this condition, substrate holder 14 with substrate 13 thereon is carried on fork 86 into reaction chamber 11. Fork 86 is stopped at a position where substrate holder 14 is situated over heater 15. Next, revolving axis 19 is moved upward to mount substrate holder 14 on heater 15 (catching), after which revolving axis 19 is stopped temporarily. For positioning, engagement is provided in the part that heater 15 and substrate holder 14 touch. Revolving axis 19 is moved for above to engage heater 15 with substrate holder 14. Next, fork 86 is pulled out of reaction chamber 11. Revolving axis 19 is then vertically moved to set substrate holder 14 so that substrate holding surface 14a of substrate holder 14 fits in aperture portion 16. For carrying-out of substrate 13, the above procedure is performed in reverse order.

Generally, the amount of source gas that outflows through the space between aperture portion 16 of flow channel 12 and substrate holder 14 is proportionate to the difference between the cross-sectional area of flow channel 12 and the area of the space. Practice shows that the amount of leakage of gas through the space is especially larger at the upstream side of the substrate. Further, as described above, variations in the space cause variations in the amount of supply of source gas onto the substrate.

The operation of reducing leakage of gas through the space between the aperture portion of the flow channel and the substrate holder, realized in this embodiment, will be described below.

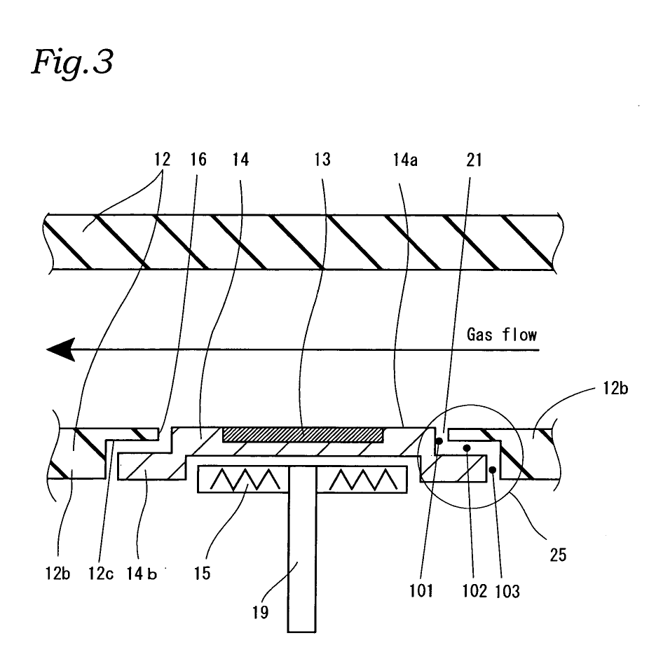

FIG. 3 is an enlarged schematic cross-section of the part of fitting of aperture portion 16 of flow channel 12 and substrate holder 14 shown in FIG. 1. As shown in the figure, in this embodiment, a means for reducing leakage of gas is of orifice structure 25 defined by aperture portion 16 of flow channel 12 and substrate holder 14.

That is, space 21 formed between aperture portion 16 of flow channel 12 and substrate holder 14 is a bent passage composed of first passage 101 extending downward from the inside of flow channel 12, second passage 102 extending in a lateral direction from the end of first passage 101, and third passage 103 extending from the end of second passage 102 down to the outside of flow channel 12. More specifically, the means for reducing leakage of gas is composed of upward dent portion 12c and brim 14b. Upward dent portion 12c is dented in an upward direction, and is provided along the periphery of aperture portion 16 and in a thickness portion of lower wall 12b of flow channel 12. Brim 14b projects from the side wall of substrate holder 14 in a lateral direction. When substrate holding surface 14a of substrate holder 14 is in a state of fitting in aperture portion 16, brim 14b fits in upward dent portion 12c while forming a space between brim 14b and upward dent portion 12c.

This structure decreases the conductance with respect to outflow of source gas even when the area of space 21 between aperture portion 16 of flow channel 12 and substrate holder 14 is the same as ever. This significantly reduces outflow of source gas through space 21, which is between aperture portion 16 of flow channel 12 and substrate holder 14, or stops the outflow. Since variations in the amount of outflow of gas are reduced, the flow of source gas becomes stable and the uniformity of crystallinity and layer thickness of thin films is secured throughout the substrate plane.

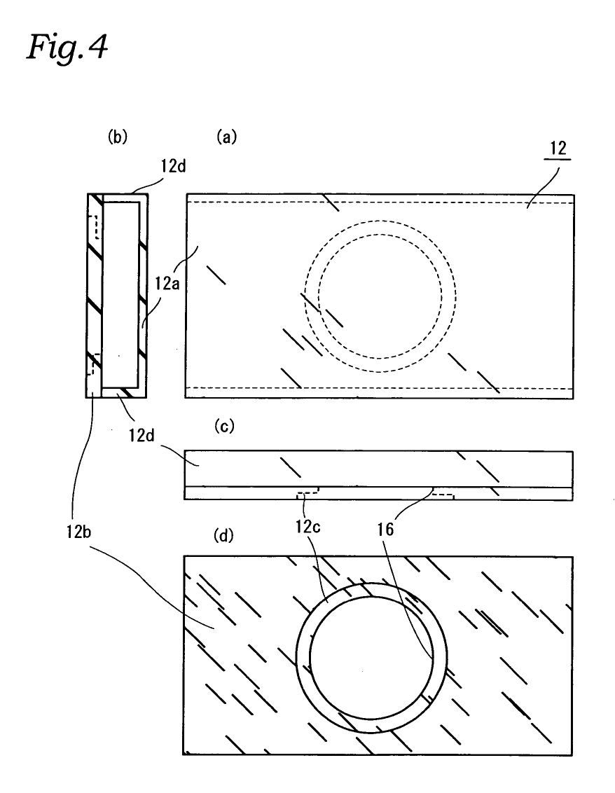

FIG. 4 is a view showing a three-dimensional shape of flow channel 12 shown in FIG. 1 according to embodiment 1. FIGS. 4(a), 4(b), 4(c), and 4(d) respectively show the upper surface, cross-section, side surface, and lower surface of flow channel 12. As shown in FIG. 4, lower wall 12b of flow channel 12 of embodiment 1 has aperture portion 16. Upward dent portion 12c that is dented in an upward direction is provided along the periphery of aperture portion 16 and in a thickness portion of lower wall 12b of flow channel 12. Upward dent portion 12c and substrate holder 14 together constitute an orifice structure. Upper wall 12a and lower wall 12b of flow channel 12 are connected together by two side walls 12d and 12d.

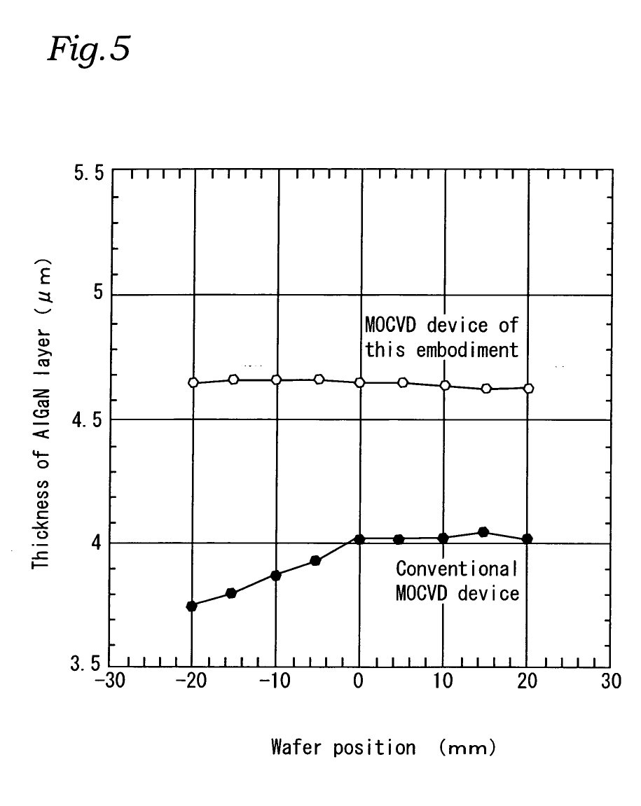

FIG. 5 is a graph of a comparison between the thickness distributions of GaN layers grown by using a conventional MOCVD apparatus and an MOCVD apparatus according to embodiment 1 of the present invention. In each example shown, a GaN layer was grown on a substrate of 2 inches. As seen from the graph, the MOCVD apparatus according to this embodiment improves the thickness distributions throughout the substrate.

Also, an AlGaN layer was grown on a substrate by using the MOCVD apparatus according to this embodiment. The Al composition and layer thickness were uniform throughout the substrate plane. Thus, crystal distortions were inhibited which would otherwise have been caused by non-uniform composition and layer thickness of the thin film on the substrate, and accordingly no cracks were found.

In this embodiment, as shown in FIG. 3, the lower surface of substrate holder 14 is lid-shaped covering the entire upper surface of heater 15 and the upper portion of the side wall of heater 15. This is for ease of positioning when substrate holder 14 is set on heater 15. The mechanism for positioning is not limited to the lid structure; the surfaces of contact may constitute a concave/convex combination.

### Embodiment 2

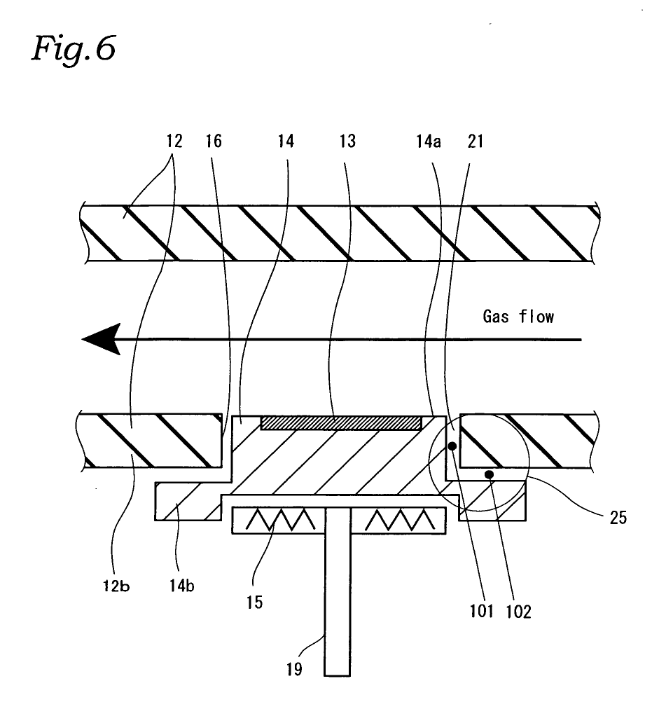

FIG. 6 is an enlarged schematic cross-section of the part of fitting of the flow channel and substrate holder according to embodiment 2 of the present invention. As shown in the figure, in this embodiment, the means for reducing leakage of gas is composed of brim 14b projecting from the side wall of substrate holder 14 in a lateral direction, while forming space 21 between brim 14b and lower wall 12b of flow channel 12, when substrate holding surface 14a of substrate holder 14 is in a state of fitting in aperture portion 16. Lower wall 12b of flow channel 12 is as conventionally designed. That is, only providing disk shaped substrate holder 14 having brim 14b provided on its periphery results in orifice structure 25 defined by aperture portion 16 of flow channel 12 and substrate holder 14. In this case, space 21, which is formed between aperture portion 16 of flow channel 12 and substrate holder 14, is a bent passage composed of first passage 101 extending downward from the inside of flow channel 12, and second passage 102 extending in a lateral direction from the end of first passage 101 to the outside of flow channel 12.

In this embodiment, as in embodiment 1, a revolving mechanism and a substrate automatic carry-in/out equipment may be provided, though not shown. While in this embodiment the three-dimensional shape of the flow channel is basically the same as that in embodiment 1, the aperture portion may be shaped similarly to the aperture portions of flow channels of conventional vapor deposition apparatuses.

This structure, as in embodiment 1, decreases the conductance with respect to outflow of source gas even when the area of space 21 between aperture portion 16 of flow channel 12 and substrate holder 14 is the same as ever.

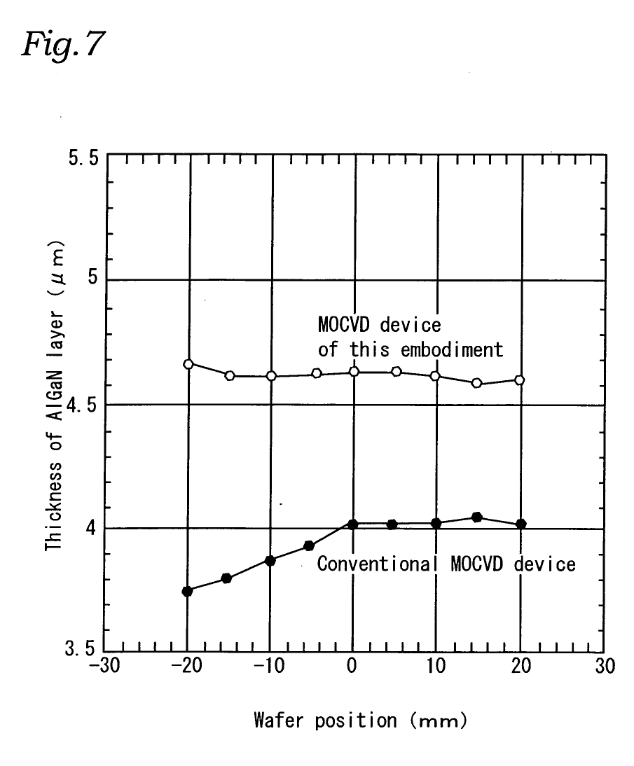

FIG. 7 is a graph of a comparison between the thickness distributions of GaN layers grown by using a conventional MOCVD apparatus and an MOCVD apparatus according to embodiment 2 of the present invention. In each example shown, a GaN layer was grown on a substrate of 2 inches. As seen from the graph, the MOCVD apparatus according to this embodiment improves the thickness distributions throughout the substrate.

With this structure, as in embodiment 1, since variations in the amount of outflow of gas were reduced, the flow of source gas became stable and the uniformity of crystallinity and layer thickness of thin films throughout the substrate plane were secured.

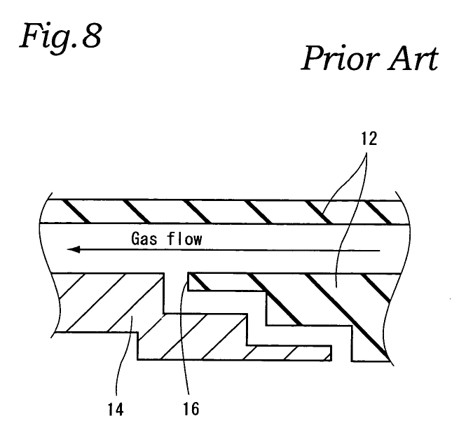

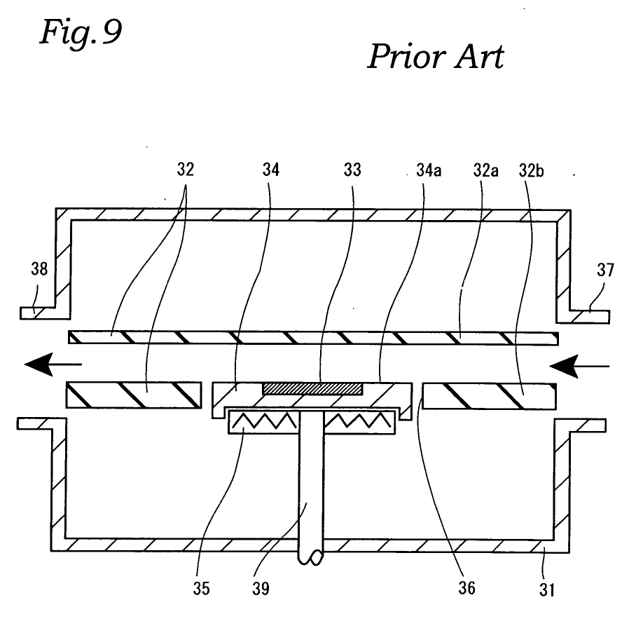

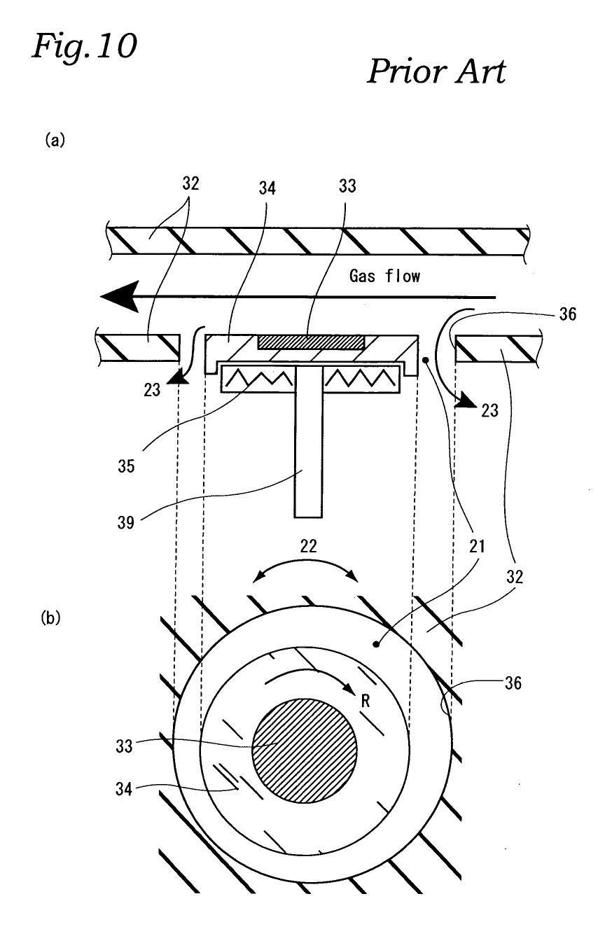

While in embodiments 1 and 2 specific examples of the orifice structure have been shown, the present invention is not limited to the examples; any orifice structure that does not allow gas to flow therethrough can be applied to the present invention. For example, as shown in FIG. 8, such an orifice structure can be conveniently used that the space between aperture portion 16 of flow channel 12 and substrate holder 14 is bent from the inside of the flow channel to the outside thereof.

The Embodiments herein described are to be considered in all respects as illustrative and not restrictive. The scope of the invention should be determined not by the Embodiments illustrated, but by the appended claims, and all changes which come within the meaning and range of equivalency of the appended claims are therefore intended to be embraced therein.

What is claimed is:

1. A vapor deposition apparatus comprising:
a substrate holder comprising a substrate holding surface for holding a substrate thereon;
a flow channel for supplying a source gas onto the substrate, the flow channel comprising an upper wall and a lower wall;
an aperture portion provided in the lower wall of the flow channel, the substrate holding surface of the substrate holder fitting in the aperture portion while forming a space between the substrate holding surface and the aperture portion; and
a means for reducing leakage of gas through the space between the aperture portion and the substrate holder.

2. The vapor deposition apparatus according to claim 1, wherein the means for reducing leakage of gas is formed by bending the space from an inside of the flow channel to an outside thereof.

3. The vapor deposition apparatus according to claim 1, wherein the means for reducing leakage of gas comprises:
an upward dent portion dented in an upward direction, the upward dent portion being provided along a periphery of the aperture portion and in a thickness portion of the lower wall of the flow channel; and
a brim projecting from a side wall of the substrate holder in a lateral direction, the brim fitting in the upward dent portion while forming a space between the brim and the upward dent portion, when the substrate holding surface of the substrate holder is in a state of fitting in the aperture portion.

4. The vapor deposition apparatus according to claim 3, wherein the space formed between the aperture portion of the flow channel and the substrate holder comprises a bent passage, the bend passage comprising a first passage extending downward from an inside of the flow channel, a second passage extending in a lateral direction from an end of the first passage, and a third passage extending from an end of the second passage down to an outside of the flow channel.

5. The vapor deposition apparatus according to claim 1, wherein the means for reducing leakage of gas comprises a brim projecting from a side wall of the substrate holder in a lateral direction, while forming a space between the brim and the lower wall of the flow channel, when the substrate holding surface of the substrate holder is in a state of fitting in the aperture portion.

6. The vapor deposition apparatus according to claim 5, wherein the space formed between the aperture portion of the flow channel and the substrate holder comprises a bent passage, the bend passage comprising a first passage extending downward from an inside of the flow channel, and a second passage extending in a lateral direction from an end of the first passage to an outside of the flow channel.

7. The vapor deposition apparatus according to claim 1, further comprising a mechanism for revolving the substrate holder.

8. The vapor deposition apparatus according to claim 1, further comprising:
a heater for heating the substrate, the substrate holder holding the substrate being mounted on the heater, the heater being vertically movable and provided below the aperture portion of the flow channel;
a mounting mechanism for mounting the substrate holder on the heater; and
a moving mechanism for moving the heater with the substrate holder mounted thereon while fitting the substrate holding surface of the substrate holder in the aperture portion of the flow channel.

9. The vapor deposition apparatus according to claim 1, the substrate holder comprises a disk comprising a brim provided along its side wall.

10. The vapor deposition apparatus according to claim 1, wherein the vapor deposition apparatus is used as an MOCVD apparatus for vapor deposition of a nitride semiconductor.
